(19) United States
(12) Patent Application Publication
(10) Pub. No.: US 2015/0036278 A1
(43) Pub. Date: Feb. 5, 2015

(54) COMPOSITE SOCKET PROBING PLATFORM FOR A MOBILE MEMORY INTERFACE

(71) Applicant: QUALCOMM Incorporated, San Diego, CA (US)

(72) Inventors: Hongjun YAO, San Diego, CA (US); Vinodh MUKUNDARAJAN, San Diego, CA (US)

(21) Appl. No.: 14/167,274

(22) Filed: Jan. 29, 2014

Related U.S. Application Data
(60) Provisional application No. 61/862,430, filed on Aug. 5, 2013.

(51) Int. Cl. H01L 27/24; H05K 3/32

(52) U.S. Cl. CPC H01L 27/24; H05K 3/32
USPC 361/679.31; 29/832

(57) ABSTRACT

A method and apparatus for composite socket probing for a mobile memory interface. An embodiment provides an integrated circuit package that includes a memory supported by an interposer. The interposer is also removably coupled to a package controller through a first socket. A clamp operates to provide clamping force to couple the interposer and the package controller with the first socket and also with a second socket.

### CLAIM OF PRIORITY UNDER 35 U.S.C. §119

The present application for Patent claims priority to Provisional Application No. 61/862,430 entitled “Composite socket probing platform of a mobile memory interface” filed Aug. 5, 2013, and assigned to the assignee hereof and hereby expressly incorporated by reference herein.

### BACKGROUND

1. Field

The present disclosure relates generally to integrated circuit design. More particularly, the present disclosure related to a composite socket probing platform of a mobile memory interface for use in testing the mobile memory interface.

2. Background

As use of mobile devices grows, so does the need to manufacture and test new devices in an efficient manner. Testing is crucial for the logic devices and memory devices incorporated into most mobile devices. Low power double data rate memory (LPDDR), which may also be referred to as mobile double data rate (MDDR), is a synchronous double data rate memory which is often used in mobile devices. The various LPDDR interfaces (such as LPDDR2/3) may be unterminated interfaces. An unterminated interface means that the input of the DRAM is directly connected to the output of the controller (MSM) without any external termination. Characterization of such interfaces involves probing a DDR signal at high speed, often in the 1 gigahertz (GHZ) range, without a termination on board that complies with the Joint Electron Device Engineering Council (JEDEC) standard. Probing may be especially complex when a package-on-package (POP) form factor is involved, as many items that must be accessed during testing are not readily accessible. Prior solutions have attempted to address this challenge, however, they have not proved suitable for high volume data collection.

There is a need in the art for methods and apparatus for methods and apparatus suitable to high volume data collection of LPDDR memory. More particularly, there is a need in the art for a composite socket probing platform for a mobile memory interface that allows for volume data collection.

### SUMMARY

Embodiments disclosed herein provide a method and apparatus for composite socket probing for a mobile memory interface. An embodiment provides an integrated circuit package that includes a memory supported by an interposer. The interposer is also removably coupled to a package controller through a first socket. A clamp operates to provide clamping force to couple the interposer and the package controller with the first socket and also with a second socket.

A further embodiment provides an apparatus that includes a memory supported by an interposer and also provides a first means for removably coupling a package controller to the interposer, a second means for removably coupling the package controller to a printed circuit board, and a means for providing contact force to couple the interposer and the package controller with the first means and the second means of the printed wiring board.

A still further embodiment provides a method for probing a memory interface. The method comprises the steps of: installing a memory on an interposer; coupling a package controller to the interposer with a first socket, wherein the coupling is removable; clamping the interposer and the package controller with the first socket and a second socket of a printed wiring board; and then probing the memory interface using the probe area.

### BRIEF DESCRIPTION OF THE DRAWINGS

FIG. 1 is a block diagram of a wireless mobile device that includes a multi-processor system having a graphics processing unit (GPU), according to an embodiment.

FIG. 2 is a block diagram illustrating a reduction of double counting within a mobile memory interface in accordance with certain embodiments of the disclosure.

FIG. 3 is a block diagram depicting an interposer measurement platform, according to an embodiment of the disclosure.

FIG. 4 illustrates in block diagram form a composite socket probing platform for a mobile memory interface, according to an embodiment.

FIG. 5 illustrates an exemplary wireless communication system in which embodiments may be advantageously employed.

FIG. 6 depicts a design workstation used for circuit, layout, and logic design of a semiconductor component according to an embodiment.

FIG. 7 illustrates a flow chart of a method for reduction of double counting within a mobile memory interface in accordance with certain embodiments of the disclosure.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

As used in this application, the terms “component,” “module,” “system” and the like are intended to include a computer-related entity, such as, but not limited to hardware, firmware, a combination of hardware and software, software, or software in execution. For example, a component may be, but is not limited to being, a process running on a processor, a processor, an object, an executable, a thread of execution, a program and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets, such as data from one component interacting with another component in a local system, distributed system, and/or across a network such as the Internet with other systems by way of the signal.

As used herein, the term “determining” encompasses a wide variety of actions and therefore, “determining” can include calculating, computing, processing, deriving, investigating, looking up (e.g., looking up in a table, a database or another data structure), ascertaining and the like. Also, “determining” can include resolving, selecting choosing, establishing, and the like.

The phrase “based on” does not mean “based only on,” unless expressly specified otherwise. In other words, the phrase “based on” describes both “based only on” and “based at least on.”

Moreover, the term “or” is intended to man an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

The various illustrative logical blocks, modules, and circuits described in connection with the present disclosure may be implemented or performed with a general purpose processor, a digital signal processor (DSP), an application specific integrated circuit (ASIC), a field programmable gate array (FPGA), or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core or any other such configuration.

The steps of a method or algorithm described in connection with the present disclosure may be embodied directly in hardware, in a software module executed by a processor or in a combination of the two. A software module may reside in any form of storage medium that is known in the art. Some examples of storage media that may be used include RAM memory, flash memory, ROM memory, EPROM memory, EEPROM memory, registers, a hard disk, a removable disk, a CD-ROM, and so forth. A software module may comprise a single instruction, or many instructions, and may be distributed over several different code segments, among different programs and across multiple storage media. A storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in software, the functions may be stored as one or more instructions on a computer-readable medium. A computer-readable medium may be any available medium that can be accessed by a computer. By way of example, and not limitation, a computer-readable medium may comprise RAM, ROM, EEPROM, CD-ROM or other optical disk storage, magnetic disk storage, or other magnetic storage devices, or any other medium that can be used to carry or store desired program code in the form of instructions or data structures and that can be accessed by a computer. Disk and disc, as used herein, includes compact disk (CD), laser disk, optical disc, digital versatile disk (DVD), floppy disk, and Blu-ray® disc where disks usually reproduce data magnetically, while discs reproduce data optically with lasers.

Software or instructions may also be transmitted over a transmission medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of transmission medium.

Further, it should be appreciated that modules and/or other appropriate means for performing the methods and techniques described herein, such as those illustrated by FIGS. X and X, can be downloaded and/or otherwise obtained by a mobile device and/or base station as applicable. For example, such a device can be coupled to a server to facilitate the transfer of means for performing the methods described herein. Alternatively, various methods described herein can be provided via a storage means (e.g., random access memory (RAM), read only memory (ROM), a physical storage medium such as a compact disc (CD) or floppy disk, etc.), such that a mobile device and/or base station can obtain the various methods upon coupling or providing the storage means to the device. Moreover, any other suitable technique for providing the methods and techniques described herein to a device can be utilized.

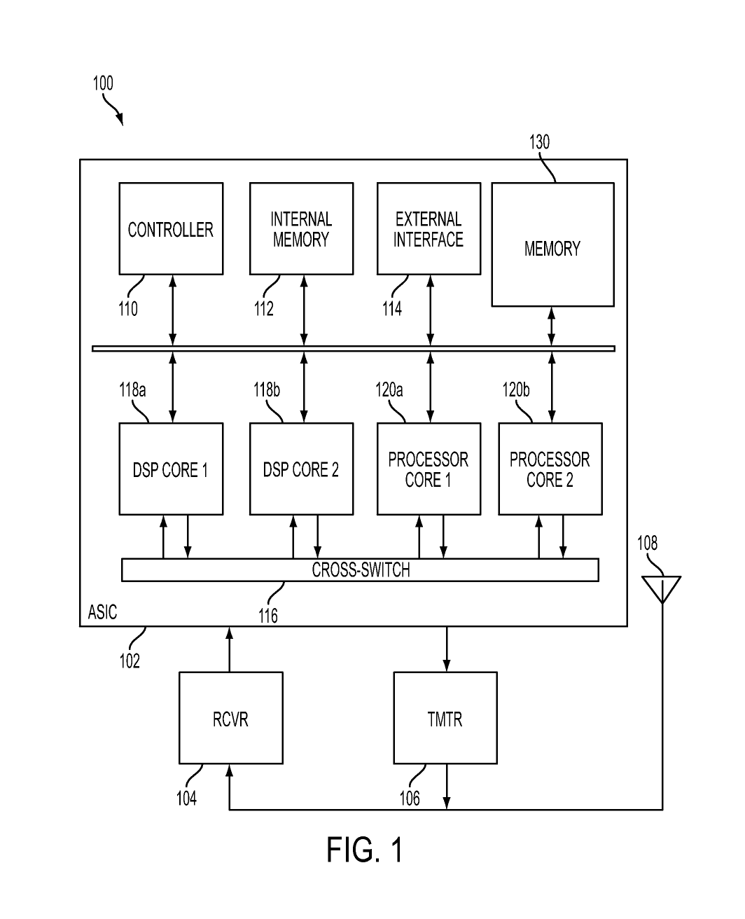

FIG. 1 shows a block diagram of a wireless mobile device 100 that includes a multi-processor system having a mobile memory 130 according to one aspect of the disclosure. The wireless mobile device 100 may monitor and/or communicate with one or more wireless communication systems. On the receive path, an antenna 108 receives signals transmitted by base stations and/or satellites and provides a received signal to a receiver (RCVR) 104. The receiver 104 processes, that is, filters, amplifies, frequency downconverts, and digitizes the received signal and provides samples to an application specific integrated circuit (ASIC) 102 for further processing. On the transmit path, the ASIC 102 processes the data to be transmitted and then provides that data to a transmitter (TMTR) 106. The transmitter 106 processes, that is, converts to analog, filters, amplifies, and frequency upconverts the data chips and generates a modulated signal, which is then transmitted by antenna 108.

ASIC 102 includes various processing units that support multi-threaded operation. For the configuration depicted in FIG. 1, the ASIC 102 includes digital signal processor (DSP) cores 118A and 118B, processor cores 120A and 120B, cross-switch 116, controller 110, internal memory 112, and external interface unit 114. The DSP cores 118A and 118B, as well as processor cores 120A and 102B support additional functions, including but not limited to, video audio, graphics, gaming, and similar functions. Each processor core may be a reduced instruction set computing (RISC) machine, a microprocessor, or similar type of processing device.

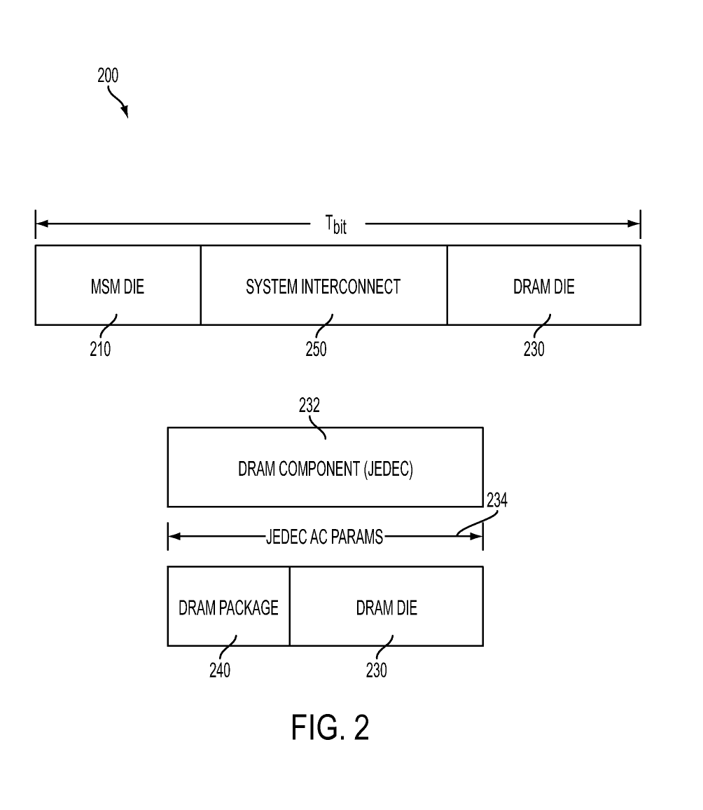

In this configuration, controller 110 controls the operation of the processing units within ASIC 102. Internal memory 112 stores data and program codes used by the processing units within the ASIC 102. In general, ASIC 102 may include fewer, additional and/or different processing units than those depicted in FIG. 1. The number of processing units and the types of processing units included in ASIC 102 may depend on various factors, including the communication system, applications, and functions supported by the multi-processor system of wireless mobile device 100. Although not illustrated, wireless mobile device 100 is battery powered. In an aspect of the disclosure, ASIC 102 may include a mobile station modem (MSM), such as that illustrated in FIG. 2.

FIG. 2 is a block diagram illustrating the reduction of double counting within a mobile memory interface according to one aspect of the present disclosure. Although this example is described with reference to a LPDDR4 interface, the scope of the disclosure is not limited to that configuration. For an LPDDR4 operating a 4.267 Gb/s, the data unit interval (UI) is only 235 picoseconds. As shown in FIG. 2, the timing of the LPDDR4 interface may be simplified into three partitions: the SoC 210, labeled here as MSM DIE, system interconnect 250, and DRAM die 230. As illustrated in FIG. 2, however, the DRAM definition includes a portion of the channel, that is, that part of the channel associated with DRAM package 240 (specifically DRAM components (JEDEC) 232 and JEDEC AC PARAMS 234). In an aspect of the disclosure, the DRAM package is de-embedded from the overall channel response. Specifically, this may include model manipulation and introduction of timing metrics that exploit the nature of pattern dependent jitter.

Because of the space constraints in mobile applications, package-on-package (POP) memory is frequently used. One of the challenges of the POP topology is that the SoC memory channel may be inaccessible from the outside, thus making it impossible to characterize the in-system signal integrity of the interface. Generally, system integrity has been measured with respect to the JEDEC specified channel and loading conditions. This may significantly alter the nature of the signaling, and make application of design advancements difficult to apply.

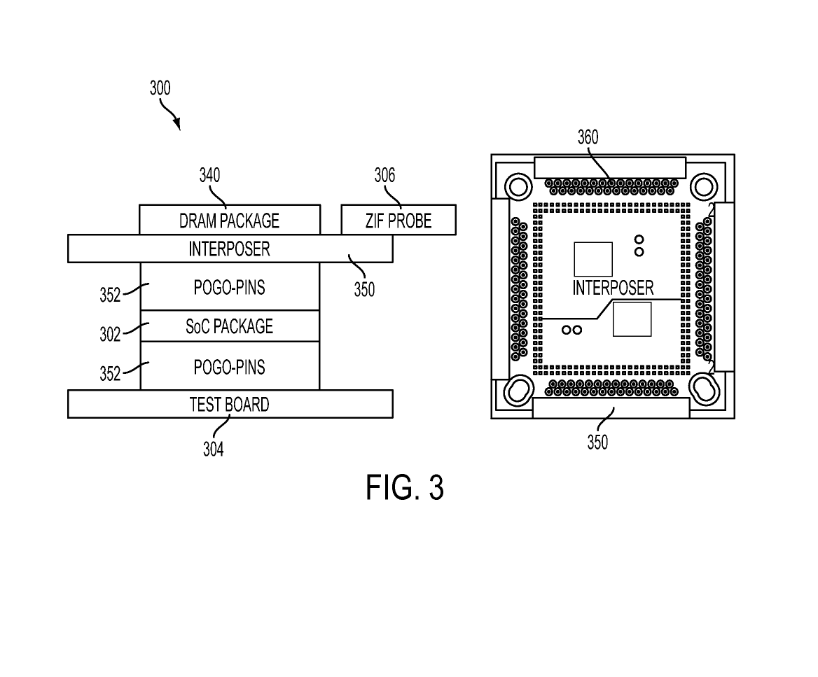

FIG. 3 provides a block diagram of an interposer measurement platform 300 in accordance with a further aspect of the disclosure. In this configuration, interposer measurement platform 300 routes a variety of signals and power nets for probing. Probing area 360, situated on a periphery of interposer 350 allows probing of signals and power nets. While interposer 350 renders signals accessible, it adds further challenges. For example, interposer 350 adds new and additional transmission line characteristics into the chip-to-chip channel, and as a result, may alter signal characteristics. Additional stubbing effects may be reduced by careful design of interposer 350 to take these effects into account. In one example, interposer 350 may be characterized and de-embedded to correlate well with silicon devices.

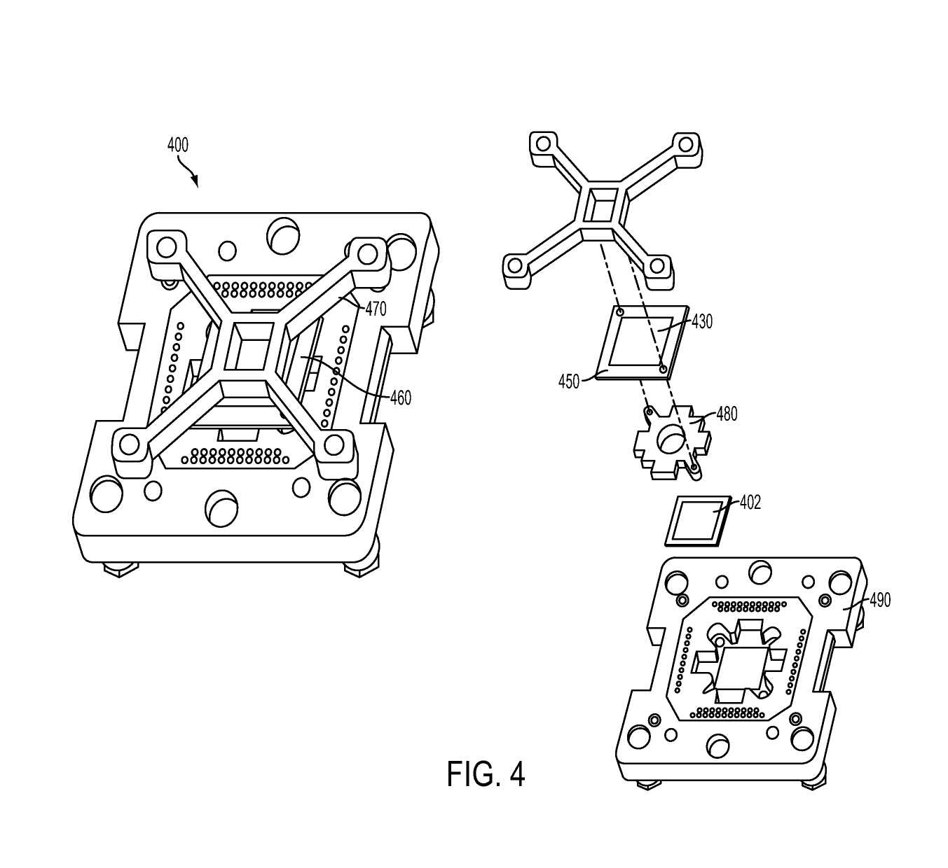

A cross-section of interposer measurement platform 300 includes interposer 350 which supports DRAM package 340. In this embodiment, SoC package 302 is coupled to interposer 350 using physical compression. This physical compression may be supplied through the use of pogo pins 352. This permits SoC package 302 to be interchangeable. In addition, pogo pins 352 enable remover of interposer 350. In this embodiment, probing area 360 is accessed using probe 306. A test board may support interposer measurement platform 300. Interposer measurement platform 300 is depicted in greater detail in FIG. 4.

FIG. 4 is a block diagram depicting a composite socket probing platform 400 for a mobile memory interface, according to an embodiment. As mentioned above, conventional probing is challenging as the DDR interface may have as many as 60 pins per channel.

DDR is an unterminated interface, even at speeds above 1 GHz in clock frequency. At the system level, circuit board design constraints are quite strict for DDR input and output, which may lead to use of a POP package for a mobile memory interface. This mobile memory interface may be an LPDDR2 or LPDDR3 interface. Due to the massive number of pins, DDR may be characterized primarily using automated test equipment with a terminated set up. True unterminated DDR probing is not available across process-voltage-temperature (PVT) variations at 1 GHz speeds and higher speeds.

FIG. 4 illustrates a two socket composite solution according to an embodiment. FIG. 4 provides an assembled view as well as an exploded view of the socketed probing solution. In this embodiment, the DRAM is soldered onto probing interposer 450. Probing interposer 450 may be fabricated at reduced cost. The MSM POP package 402 is coupled to both a second socket 490 of a load board, providing a downward connection. Probing interposer 450 provides an upward connection through two sockets. In this embodiment, MSM POP package 402 is coupled to probing interposer 450 using first socket 480. This allows both MSM POP package 402 and probing interposer 450 to be replaced easily. First socket 480 may be formed from a non-conductive material such as Torlon, that is operable to capture an array of interconnects (e.g., spring probes, pogo pins, and the like).

A clamp 470, which may be a bolt on Xshaped clamp as illustrated in FIG. 4, provides contact force for enabling socket connection and access to the probing area 460 on probing interposer 450. In this embodiment, signals of interest are brought out through the probing are 460. These signals may be brought out through the use of gold plated through hole vias. The traces that provide probing are 460 may be a few millimeters long. It may be desirable to use reduced line or trace widths in order to minimize capacitive loading on the signals. First socket 480, between probing interposer 450 and MSM POP 402 may use spring probes, such as pogo pins to further reduce capacitive loading.

A further embodiment provides improved handling of un-bounded noise sources as well as exploitation of statistical relief As is typical with high speed designs random jitter (RJ) is the jitter component that acts to close the “data eye” over the long term, assuming that the deterministic jitter is kept in check. However, in the memory interface space, random jitter is considered insignificant. At LPDDR4 speeds, and at the low bit error ration (BER) target of 1e⁻¹⁸, the contribution of the relative random jitter can no longer be ignored.

In an embodiment, the timing budget may accurately account for both random and deterministic jitter, with respect to a suitable BER. Such a timing budget not only provides increased analytic accuracy, but also facilitates more efficient use of available link timing.

In a further embodiment, an interposer measurement platform is described. The interposer measurement platform includes a memory supported by the interposer. The interposer measurement platform may include a first means for removably coupling a package controller to the interposer. The first means may be first socket 480 and/or pogo pings 352. The interposer measurement platform may also include second means for removably coupling the package controller to a printed circuit board. Second means may be second socket 490 and/or pogo pins 352. In addition, the integrated circuit package may further include means for providing contact force to couple the interposer and package controller with the first means and the second means of the printed circuit board. The providing means may be clamp 470. In a further aspect, the means may be any suitable module of apparatus that perform the above-described function.

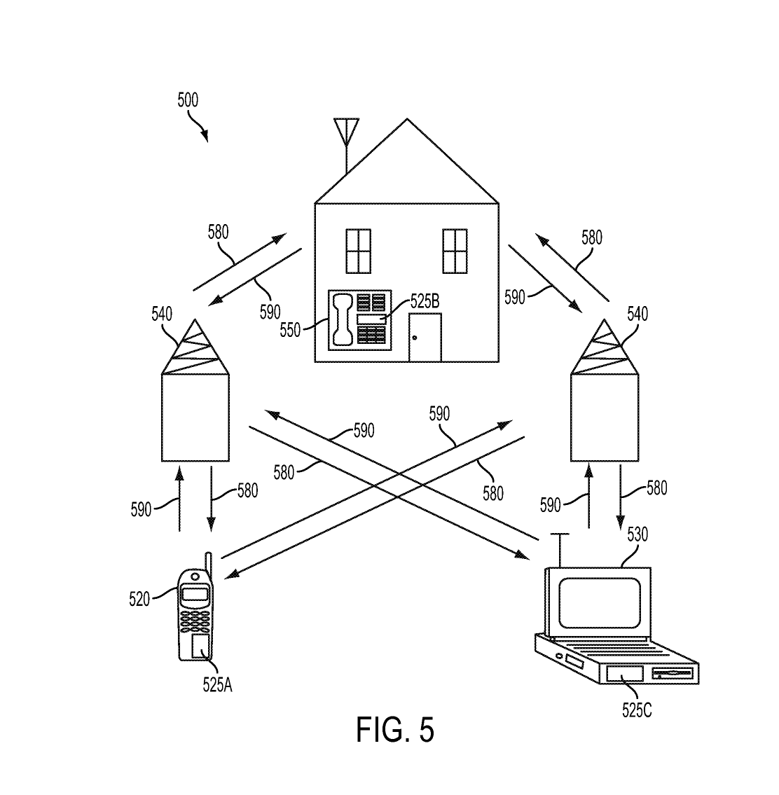

FIG. 5 is a block diagram depicting an exemplary wireless communication system 500 which may advantageously use aspects described herein. For illustration purposes, FIG. 5 shows three remote units 520, 530, and 550, along with two base stations 540. It will be understood that wireless communication systems may have many more remote units and base stations then illustrated in FIG. 5. Remote units 520, 530, and 550 include integrated circuit (IC) devices 525A, 525B, and 525C, which include the disclosed interposer measurement circuitry. Any device containing an IC may also include the interposer measurement circuitry described herein. This permits base stations, switching devices, and network equipment to also include the circuitry described herein. FIG. 5 illustrates forward link signals 580 from two base stations 540 to remote units 520, 530, and 550, with reverse link signals 590 from remote units 520, 530, and 55 to base stations 540.

As shown in FIG. 5, one of the remote units 520 is shown as a mobile telephone, while remote unit 530 is illustrated as a computer, such as a portable computer. Remote unit 550 is depicted as a fixed location remote unit in a wireless local loop system. For example, the remote units may be mobile phones, hand-held personal communication systems (PCS) units, portable data units such as personal digital assistants (PDA), GPS enabled devices, navigation devices, set top boxes, music players, video players, entertainment units, fixed location data units such as meter reading equipment, or any other device that stores or retrieves data or computer instructions, or any combination thereof. Although FIG. 5 illustrates remote units according to the embodiments described herein, the disclosure is not limited solely to the units described or depicted. Aspects of the disclosure may be installed in any device that includes interposer measurement circuitry.

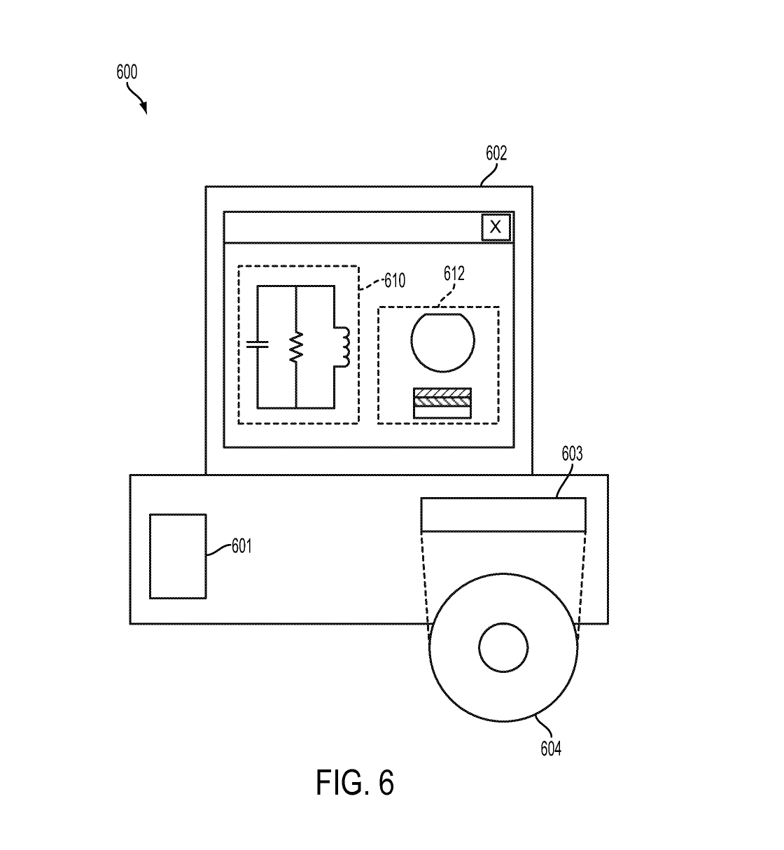

FIG. 6 is a block diagram of a design workstation used for circuit design, layout, and logic design. Such a design may be used to the system MMU circuitry disclosed above. Design workstation 600 also includes a display to facilitate circuit design 610 or semiconductor component 612, such as a packaged integrated circuit having interposer measurement circuitry. Storage medium 604 stores circuit design 610 or semiconductor component 612 design. Storage may also be provided in a file format such as GDSII or GERBER. Storage medium 604 may be a CD-ROM, DVD, hard disk, flash memory, or other appropriate device. Furthermore, design workstation 600 includes drive apparatus 603 that accepts input or provides output from storage medium 604.

Data recorded on storage medium 604 may specify logic or circuit configurations, pattern data for photolithography masks, or mask pattern data for serial write tools such as electron beam lithography. That data may further include logic verification data such as timing diagrams or net circuits associated with logic simulations. Providing data on storage medium 604 facilitates the design process or the circuit design 610 or semiconductor component 612 by decreasing the steps required to design a semiconductor wafer.

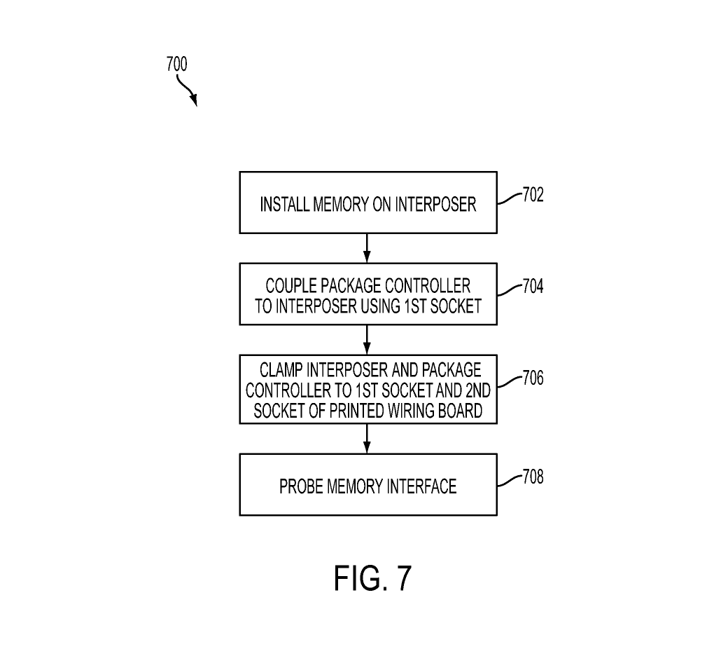

FIG. 7 provides a flowchart of a method of probing a composite socket for a mobile memory device. The method 700 begins when a memory is installed on an interposer in step 702. A package controller is then coupled to the interposer using a first socket in step 704. At this point, in step 706, the interposer and package controller are clamped to a first socket and a second socket of the printed wiring board. Once the interposer and package controller are properly clamped in place, the memory interface may be probed, in step 708.

For a firmware and/or software implementation, the methodologies may be implemented with modules (e.g., procedures, functions, and the like) that perform the functions described herein. Any machine-readable medium tangibly embodiying instructions may be used in implementing

It is understood that the specific order or hierarchy of steps in the processes disclosed is an illustration of exemplary approaches. Based upon design preferences, it is understood that the specific order or hierarchy of steps in the processes may be rearranged. The accompanying method claims present elements of the various steps in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. An integrated circuit package, comprising:
a memory supported by an interposer,
a package controller removably coupled to the interposer using a first socket; and
a clamp operable to provide contact force to couple the interposer and the package controller with the first socket and a second socket of the printed wiring board.

2. The integrated circuit package of claim 1, wherein the package controller is a modem.

3. The integrated circuit package of claim 1, wherein the memory is coupled to the interposer using a third socket.

4. The integrated circuit package of claim 1, wherein the memory is a low power double data rate memory. (LPDDR).

5. The integrated circuit package of claim 1, wherein the clamp is further operable to enable alignment between the interposer and the package controller through the first socket.

6. An integrated circuit package, comprising:
a memory supported by an interposer;
first means for removable coupling a package controller to the interposer;
second means for removably coupling the package controller to a printed circuit board; and
means for providing contact force to couple the interposer and the package controller with the first means and the second means of the printed wiring board.

7. The integrated circuit package of claim 6, wherein the package controller is a modem.

8. The integrated circuit package of claim 6, further comprising a third means for coupling the memory to the interposer.

9. The integrated circuit package of claim 6, in which the memory comprises a low power double data rate memory (LPDDR).

10. The integrated circuit package of claim 6, further comprising further means for aligning the interposer and the package controller through the first means.

11. A method for probing a memory interface, comprising:
installing a memory on an interposer;
coupling a package controller to the interposer with a first socket, wherein the coupling is removable;
clamping the interposer and the package controller with the first socket and a second socket of a printed wiring board; and
probing the memory interface.

12. The method of claim 11, wherein the package controller is a modem.

13. The method of claim 11, further comprising coupling the memory to the interposer with a third socket.

14. The method of claim 11, wherein the memory comprises a lower power double data rate memory (LPDDR).

15. The method of claim 11, further comprising aligning the interposer and the package controller through the first socket.
